(19) United States
(12) Patent Application Publication
(10) Pub. No.: US 2003/0022532 A1
(43) Pub. Date: Jan. 30, 2003

(54) Electrical contact

(76) Inventors: Bradley E. Clements, Ft Collins, CO (US); Joseph M. White, Windsor, CO (US)

Correspondence Address: HEWLETT-PACKARD COMPANY, Intellectual Property Administration, P.O. Box 272400, Fort Collins, CO, 80527-2400, US

(21) Appl. No.: 09/917,361

(22) Filed: Jul. 27, 2001

(51) Int. Cl. H05K 1/00

(52) U.S. Cl. 439/66

(57) ABSTRACT

An electrical contact is designed with a plurality of spiraling legs such that when compressed, the spiral legs create a rotation of the top of the contact resulting in a wiping action to the contacting device or pad. The resulting micro-spider contact may be used for a wide variety of non-permanent or permanent electrical connection purposes including use in construction of an interposer.

### FIELD OF THE INVENTION

This invention relates generally to the field of electrical contacts and more specifically to the field of electrical contacts incorporating a wiping action.

### BACKGROUND OF THE INVENTION

In designing electrical devices, modular structures are often used to allow nonpermanent attachment of modules. This allows for upgrading or repairing of devices without requiring expensive reworking of the circuit board. Non-permanent attachment of modules also allows field replacement of defective or out-of-date modules. Reusable non-permanent electrical contacts require the ability to make reliable electrical contacts with a module over repeated connection and disconnection of the contacts. The contacts also are required to withstand a large number of connection and disconnection cycles without sustaining damage. Also, as electrical designs shrink in size there is pressure to design reliable contacts as small as possible.

One specific type of electrical contact is an interposer. Interposers are placed between two electrical devices. One of the devices may be a circuit such as a multi-chip module (MCM) and the other may be a printed circuit board. As electrical devices shrink in size, interposers must also allow for increased contact densities while still allowing repeated, reliable electrical contacts. Existing electrical contact designs include interposers constructed from elastomeric material and interposers constructed from balls of wire. Both of these solutions have limitations inherent in their design. Current elastomeric materials are unable to sustain adequate contact spring force over time and temperature and have a small range of working heights. Interposers constructed from balls of wire are fragile, often prone to unravel, require costly inspection, and provide a limited amount of contact travel.

### SUMMARY OF THE INVENTION

An electrical contact is designed with a plurality of spiraling legs such that when compressed, the spiral legs create a rotation of the top of the contact resulting in a wiping action to the contacting device or pad. The resulting micro-spider contact may be used for a wide variety of non-permanent or permanent electrical connection purposes including use in construction of an interposer.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is a perspective view of an embodiment of a micro-spider contact according to the present invention.

FIG. 2A is a top view of an embodiment of a clockwise micro-spider contact according to the present invention.

FIG. 2B is a top view of an embodiment of a counter-clockwise micro-spider contact according to the present invention.

FIG. 3 is an oblique view of a plurality of micro-spider contacts according to an embodiment of the present invention.

FIG. 4 is a cross-sectional view of an embodiment of the present invention illustrating micro-spiders constructed on opposite sides of a substrate.

FIG. 5A is a cross-sectional view of an embodiment of the present invention illustrating a single pair of micro-spider contacts.

FIG. 5B is a cross-sectional view of an embodiment of the present invention illustrating a single pair of micro-spider contacts.

FIG. 6 is an oblique view of an embodiment of the present invention illustrating a single clockwise micro-spider and a single micro stop.

FIG. 7 is a cross-sectional view of an embodiment of the present invention illustrating a single pair of micro-spiders and a single pair of micro stops.

FIG. 8 is a perspective view of an embodiment of a three-legged counter-clockwise micro-spider according to the present invention.

FIG. 9 is a perspective view of an embodiment of an array of three-legged counter-clockwise micro-spiders according to the present invention.

FIG. 10 is a cross-sectional view of an embodiment of the present invention illustrating micro-spiders constructed on a first side of a substrate and ball grid array (BGA) balls constructed on a second side of a substrate.

### DETAILED DESCRIPTION

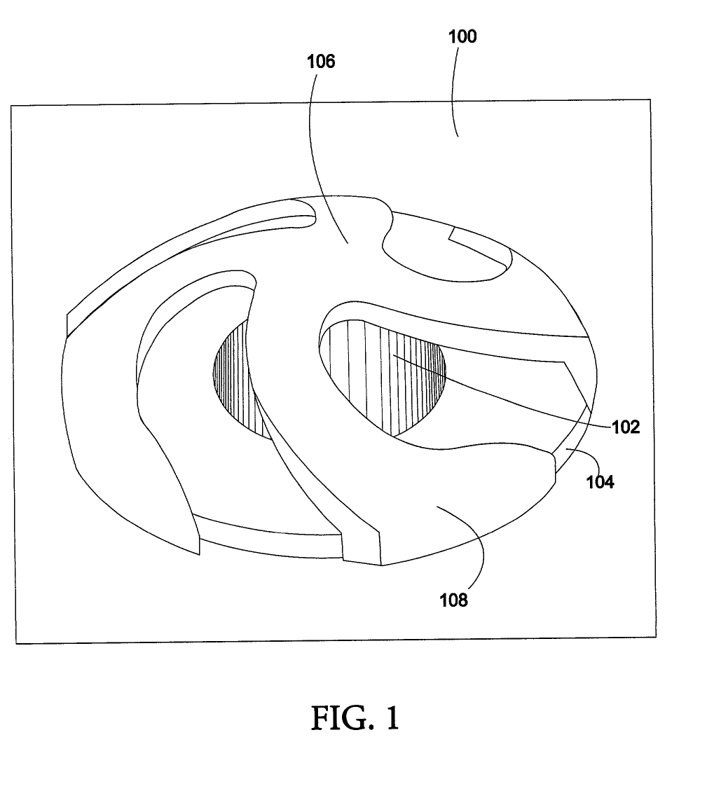

FIG. 1 is a perspective view of an embodiment of a specialized electrical contact created pursuant to the present invention referred herein to as a micro-spider contact, or simply as a micro-spider. In FIG. 1 the micro-spider 106, is an example embodiment of the present invention with four spiraling legs 108 attached to an area of metal 104 surrounding a through-plated hole 102 in a substrate 100 material. The micro-spider 106 is preferably constructed from a thin sheet of metal, and may be fabricated by a variety of methods. One method for constructing micro-spiders is described further in a U.S. patent application, Ser. No. ______, “Method for the Fabrication of Electrical Contacts”, filed concurrently with the present application, and incorporated herein by reference. Another method for the fabrication of micro-spiders is described in a U.S. patent application, Ser. No. ______, “Method for the Fabrication of Electrical Contacts”, filed concurrently with the present application, and incorporated herein by reference. Note that other embodiments of the present invention may include micro-spiders with 3 legs 108, or 5 or more spiraling legs 108. In the example embodiment of the present invention shown in FIG. 1 the legs 108 of the micro-spider 106 spiral in a clockwise direction. Note that micro-spiders 106 may be constructed with legs 108 spiraling in either a clockwise or counter-clockwise direction within the scope of the present invention. In fact, in certain applications of the concepts of the present invention it may be desirable to include both clockwise and counter-clockwise micro-spiders 106 in the same device. By mixing the two types of micro-spiders in an approximately equal amount and approximately equal distribution, the slight rotational torque applied as each micro-spider 106 contact is compressed is approximately equalized between the clockwise and counter clockwise direction, resulting in a very small net rotational torque.

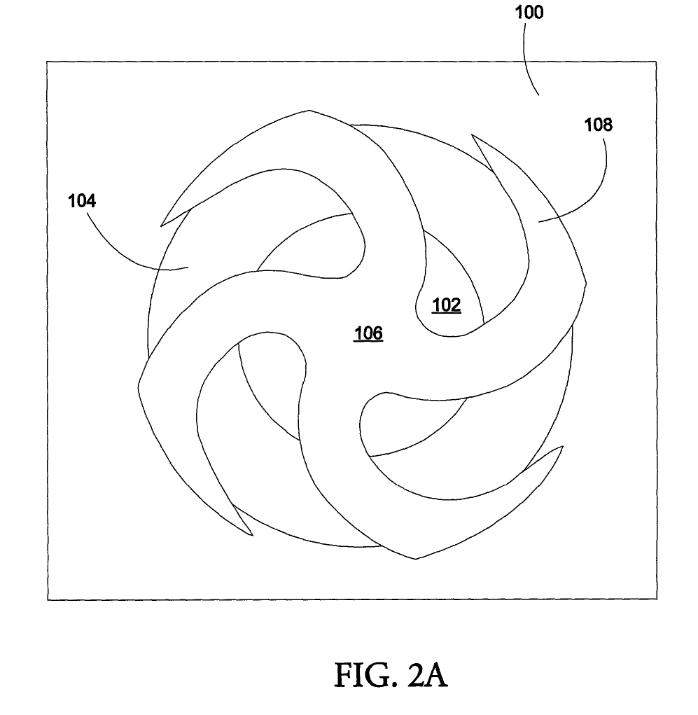

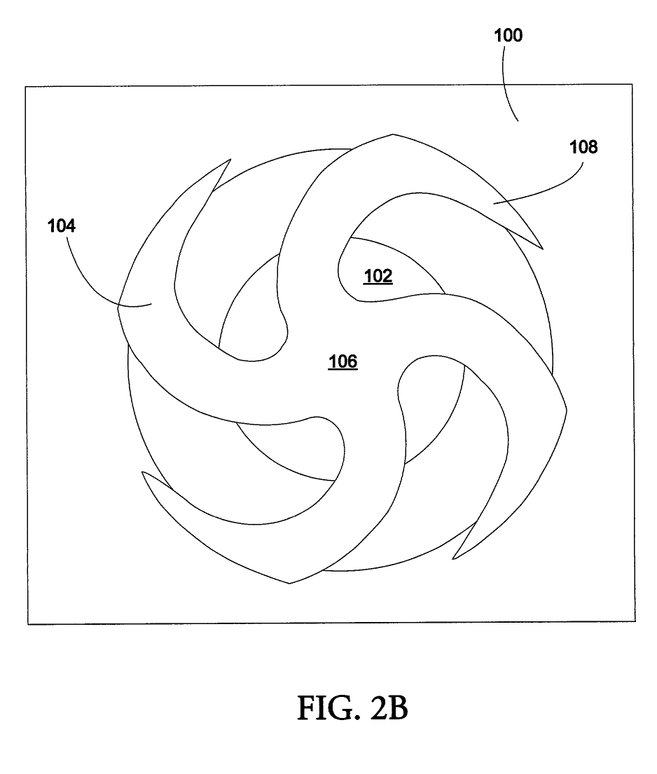

FIG. 2A is a top view of an embodiment of a clockwise micro-spider contact according to the present invention. The micro-spider 106 shown in FIG. 2A is identical to the device of FIG. 1 as seen from the top. Again, micro-spider 106, preferably includes four spiraling legs 108 attached to an area of metal 104 surrounding a through-plated hole 102 in a substrate 100 material. FIG. 2B is a top view of an embodiment of a counter-clockwise micro-spider contact according to the present invention. The micro-spider 106 shown in FIG. 2B is similar to the device of FIG. 2A except with counter-clockwise spiraling legs 108 instead of the clockwise spiraling legs 108 shown in FIG. 2A.

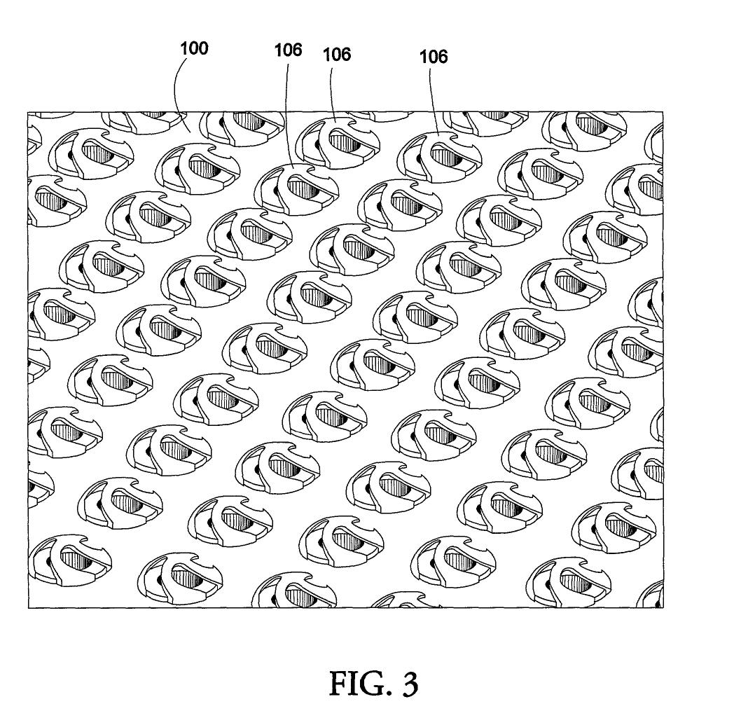

FIG. 3 is a perspective view of a plurality of micro-spider contacts according to an embodiment of the present invention. The example illustrates an array of micro-spiders 106 on a substrate 100. In this embodiment, all of the micro-spiders 106 shown are clockwise micro-spiders 106. In other embodiments of the present invention, counter-clockwise micro-spiders 106 may be used, or a combination of clockwise and counter-clockwise micro-spiders 106 may be used.

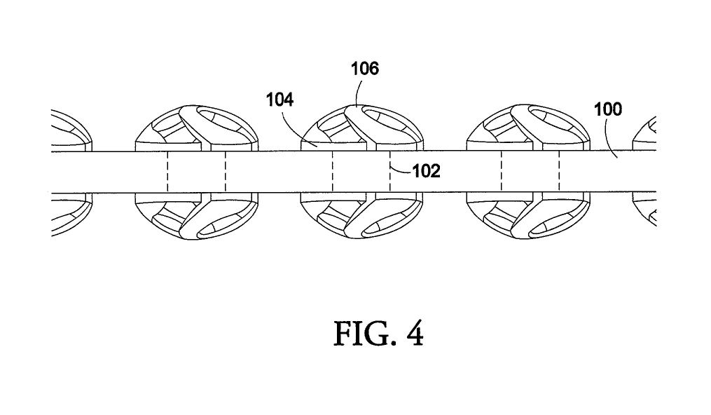

In a specific example embodiment of the present invention, micro-spiders 106 are preferably constructed on both sides of the substrate 100 creating an interposer for use in non-permanently attaching electronic devices such as a multi-chip module (MCM) to a circuit board. FIG. 4 is a cross-sectional view of such an embodiment. The example embodiment of the present invention shown in FIG. 4 illustrates a plurality of micro-spiders 106 constructed on opposite sides of a substrate 100, connected together by through-plated holes 102 surrounded by areas of metal 104 contacting the legs 108 of the micro-spiders 106. This example embodiment of the present invention may be employed as an interposer for use in non-permanently attaching electronic devices such as a MCM to a circuit board.

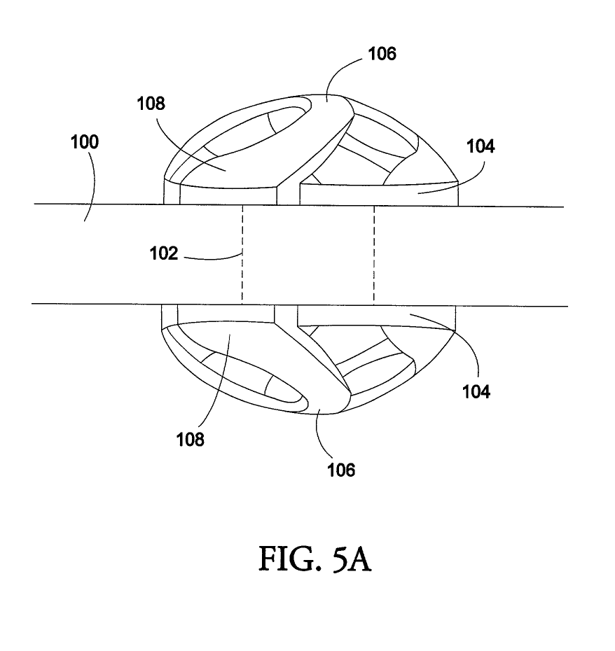

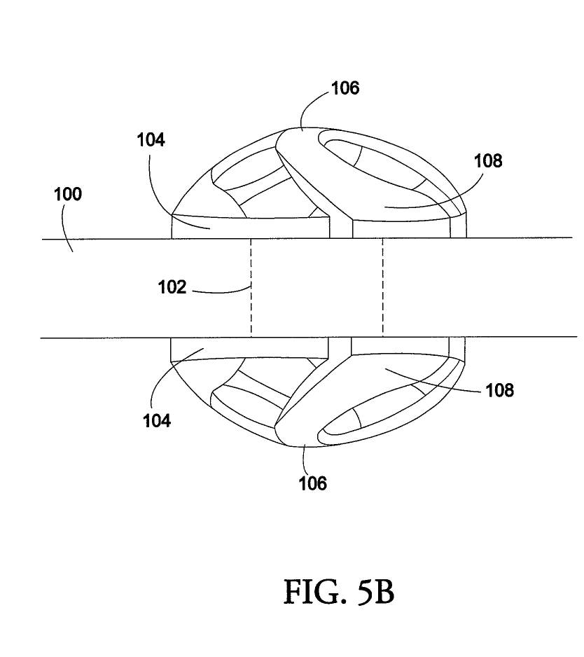

FIG. 5A is a cross-sectional view of an embodiment of the present invention illustrating a single pair of micro-spider contacts. The device of FIG. 5A illustrates a counter-clockwise micro-spider 106 similar to the device shown in FIG. 2B on the top surface of the substrate 100, and a clockwise micro-spider 106 similar to the device shown in FIG. 2A on the bottom surface of the substrate 100. The two micro-spiders 106 are preferably electrically connected to each other by a through-plated hole 102 in the substrate 100 where each hole 102 is surrounded by an area of metal 104 electrically and mechanically contacting the legs 108 of the micro-spiders 106.

FIG. 5B is a cross-sectional view of another embodiment of the present invention illustrating a single pair of micro-spider contacts. The device of FIG. 5B illustrates a clockwise micro-spider 106 similar to the device shown in FIG. 2A on the top surface of the substrate 100, and a counter-clockwise micro-spider 106 similar to the device shown in FIG. 2B on the bottom surface of the substrate 100. The two micro-spiders 106 are preferably electrically connected to each other by a through-plated hole 102 in the substrate 100 where each hole 102 is surrounded by an area of metal 104 electrically and mechanically contacting the legs 108 of the micro-spiders 106.

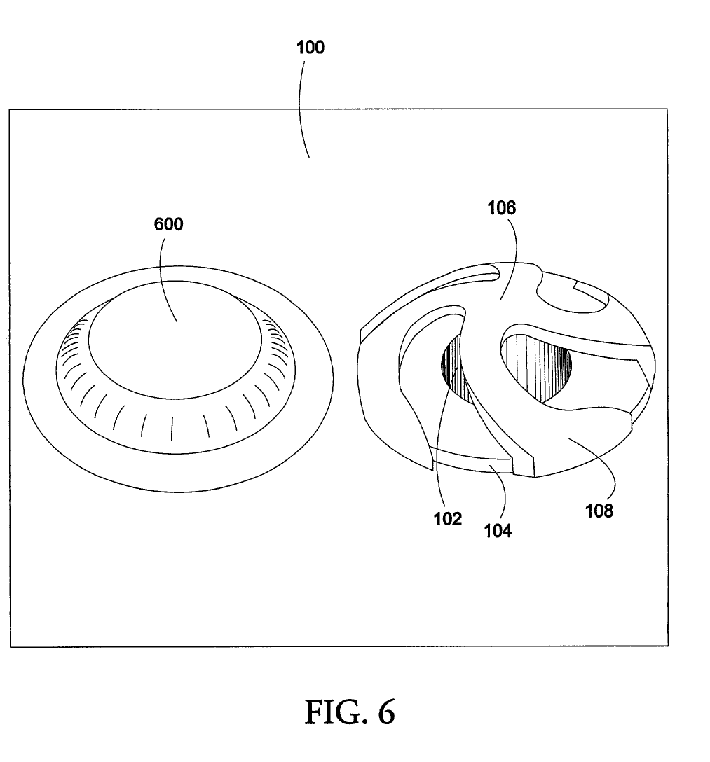

In some example embodiment of the present invention, it may be preferable to add a micro stop to prevent over-compression of the micro-spiders when connecting to a device such as a printed circuit board (PCB) or MCM. FIG. 6 is a perspective view of an embodiment of a single clockwise micro-spider and a single micro stop according to the present invention. The addition of a micro stop 600 to a device comprising at least one micro-spider 106 allows the connection of, say, a MCM to the device without over-compressing the legs 108 of the micro-spiders 106. The micro stop preferably halts further compression of the micro-spiders 106 when the devices are a predetermined distance apart, as set by the height of the micro stop 600. The example embodiment of the present invention of FIG. 6 shows a clockwise micro-spider 106 electrically connected to the metal 104 surrounding a through-plated hole 102 in a substrate 100.

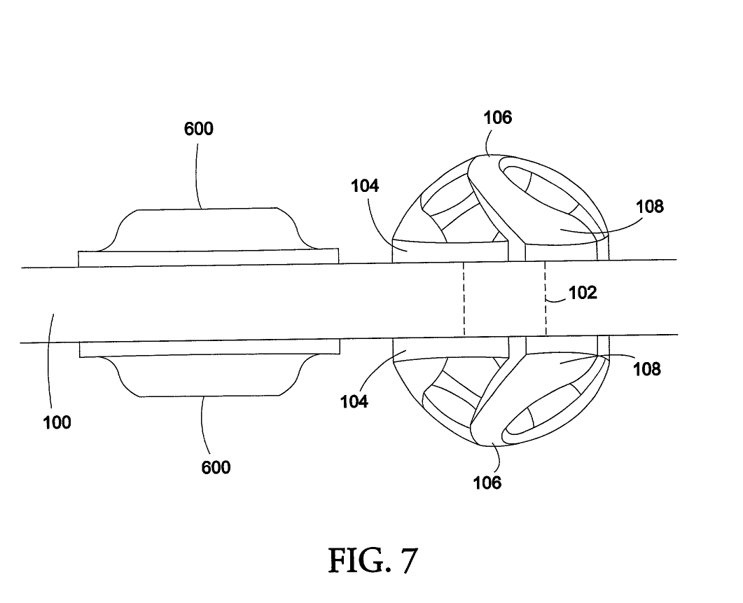

FIG. 7 is a cross-sectional view of an embodiment of a single pair of micro-spiders 106 and a single pair of micro stops 600 according to the present invention. A clockwise micro-spider 106 similar to that described in connection with FIG. 2A is shown on the top surface of the substrate 100, and a counter-clockwise micro-spider 106 similar to that described in connection with FIG. 2B is shown on the bottom surface of the substrate 100. The two micro-spiders 106 are electrically connected to each other by a through-plated hole 102 in the substrate 100 where each hole 102 is surrounded by an area of metal 104 electrically and mechanically contacting the legs 108 of the micro-spiders 106. The two micro stops 600 may be constructed by a variety of methods within the scope of the present invention. The height of the micro stops 600 is determined by the structure and materials used in creating the micro-spiders 106. The micro stops 600 are preferably short enough to allow enough compression of the micro-spiders 106 such that the spiraling legs 108 cause the top of the micro-spiders 106 to rotate slightly creating a wiping action on the device with which they are brought into contact. This wiping action may physically remove oxides or other contaminants from the device the micro-spiders 106 are contacting, thereby creating a more reliable electrical contact than would be obtained by a similar contact without any wiping action. The micro stops 600 are preferably tall enough to prevent the contacting device from over-compressing the legs 108 of the micro-spiders 106. If the legs 108 are over-compressed, they may deform or break. If the legs 108 deform, their useful life as a re-usable contact may be shortened because they may not be able to create the wiping action, and they may become brittle due to strain hardening and may eventually break.

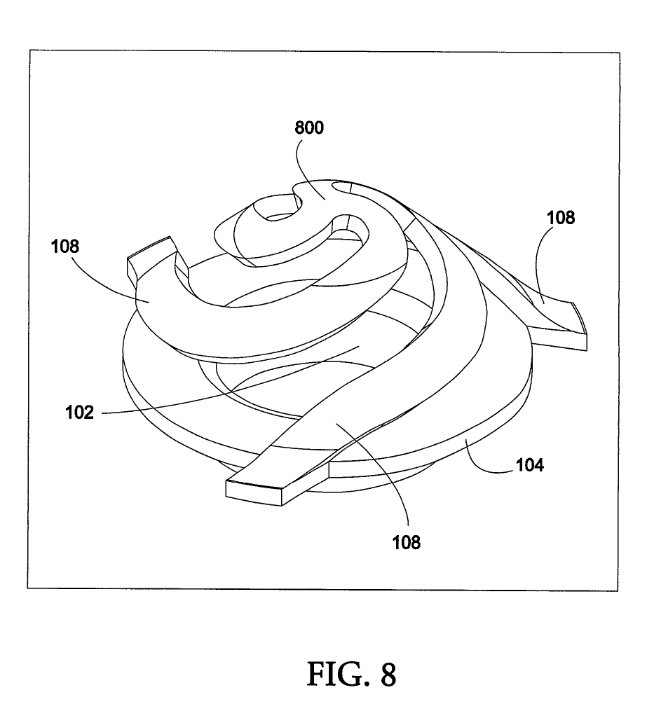

Micro-spiders may be made with a variety of numbers of legs 108. Note that any number of legs greater than one may be used in creating a micro-spider 106 within the scope of the present invention. FIG. 8 is a perspective view of an embodiment of a three-legged counter-clockwise micro-spider according to the present invention. It will be appreciated that a three-legged micro-spider 800 allows a different amount of wiping action and spring force than an equivalent four-legged micro-spider 106 previously described in connection with FIGS. 1 through 7. This three-legged micro-spider 800 embodiment of the present invention comprises spiraling legs 108 attached to an area of metal 104 surrounding a through-plated hole 102 in a substrate 100 material.

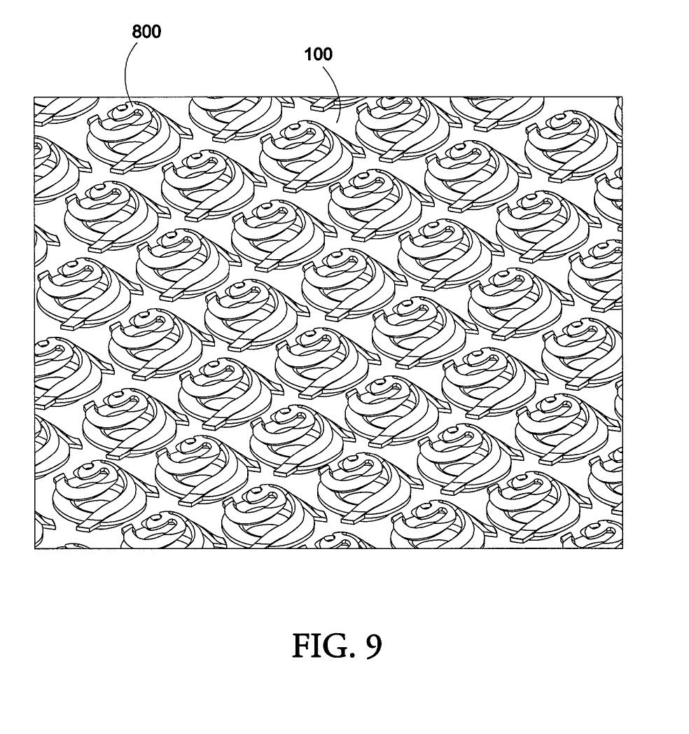

FIG. 9 is a perspective view of an embodiment of an array of three-legged counter-clockwise micro-spiders according to the present invention. In this example embodiment, all of the micro-spiders 800 shown are counter-clockwise three-legged micro-spiders 800 on a substrate 100. In other embodiments of the present invention, clockwise three-legged micro-spiders 800 may be used, or a combination of clockwise and counter-clockwise three-legged micro-spiders 800 may be used. In further embodiments of the present invention, three-legged micro-spiders 800 may be constructed on both sides of the substrate 100 creating an interposer for use in non-permanently or permanently attaching electronic devices such as a multi-chip module (MCM) to a circuit board.

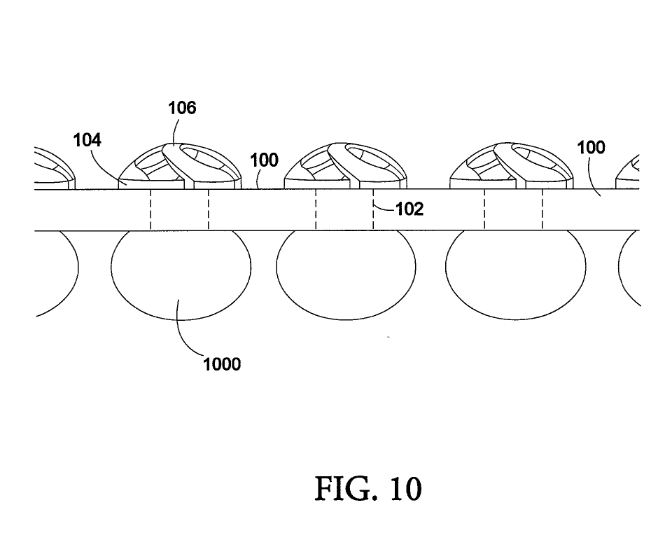

In a specific example embodiment of the present invention, micro-spiders 106 are preferably constructed on a first side of the substrate 100 and ball grid array balls 1000 are preferably constructed on a second side of the substrate 100, creating an interposer for use in non-permanently attaching electronic devices such as a multi-chip module (MCM) to a circuit board. FIG. 10 is a cross-sectional view of such an embodiment. The example embodiment of the present invention shown in FIG. 10 illustrates a plurality of micro-spiders 106 constructed on a first side of a substrate 100, and ball grid array (BGA) balls 1000 constructed on a second side of a substrate 100, connected together by through-plated holes 102 surrounded by areas of metal 104 contacting the micro-spiders 106. This example embodiment of the present invention may be employed as an interposer for use in non-permanently attaching electronic devices such as a MCM to a circuit board, while the interposer is attached to the circuit board by the BGA balls 1000.

What is claimed is:

1. An improved electrical contact comprising:
an electrical contact including spiraling legs configured to create a wiping action on a metal pad when compressed by said pad.

2. The improved electrical contact of claim 1, wherein said spiraling legs form a dome shape.

3. The improved electrical contact of claim 1, further comprising:
a micro stop of sufficient height to prevent over-compression of said spiraling legs of said electrical contact.

4. The improved electrical contact of claim 1, wherein said legs spiral in a clockwise direction.

5. The improved electrical contact of claim 1, wherein said legs spiral in a counter-clockwise direction.

6. The improved electrical contact of claim 1, wherein said electrical contact further comprises at least 2 legs.

7. The improved electrical contact of claim 1, wherein said electrical contact is constructed from copper.

8. The improved electrical contact of claim 7, wherein said copper electrical contact is plated with gold.

9. The improved electrical contact of claim 8, wherein said copper electrical contact is further plated with nickel.

10. An interposer comprising:
a plurality of electrical contacts on opposite sides of a substrate; wherein said electrical contacts include spiraling legs configured to create a wiping action on metal pads when compressed by said pads.

11. The interposer of claim 10, wherein said spiraling legs form a dome shape.

12. The interposer of claim 10, further comprising:
at least one micro stop of sufficient height to prevent over-compression of said spiraling legs of said electrical contacts.

13. The interposer of claim 12, wherein at least one micro stop is on a first side of said substrate, and at least one micro stop is on a second side of said substrate.

14. The interposer of claim 10, wherein said legs spiral in a clockwise direction.

15. The interposer of claim 10, wherein said legs spiral in a counter-clockwise direction.

16. The interposer of claim 10, wherein each of said electrical contacts comprise at least two legs.

17. The interposer of claim 10, wherein said electrical contacts are constructed from copper.

18. The interposer of claim 17, wherein said copper electrical contacts are plated with gold.

19. The interposer of claim 18, wherein said copper electrical contacts are further plated with nickel.

20. The interposer of claim 10, wherein said electrical contacts opposite from each other on said two sides of said substrate are electrically connected by through-plated holes in said substrate.

21. The interposer of claim 10, wherein said legs of said electrical contacts on a first side of said substrate spiral in a clockwise direction and said legs of said electrical contacts on a second side of said substrate spiral in a counter-clockwise direction.

22. The interposer of claim 10, wherein at least one of said legs of said electrical contacts on a first side of said substrate spiral in a clockwise direction, and at least one of said legs of said electrical contacts on a first side of said substrate spiral in a counter-clockwise direction, and at least one of said legs of said electrical contacts on a second side of said substrate spiral in a clockwise direction, and at least one of said legs of said electrical contacts on a second side of said substrate spiral in a counter-clockwise direction.

23. The interposer of claim 22, wherein substantially equal numbers of said legs of said electrical contacts on said first side of said substrate spiral in clockwise and counter-clockwise directions, and substantially equal numbers of said legs of said electrical contacts on said second side of said substrate spiral in clockwise and counter-clockwise directions.

24. The interposer of claim 19, wherein substantially equal numbers of said legs of said electrical contacts on said first and said second sides of said substrate spiral in clockwise and counter-clockwise directions.

25. An interposer comprising:
a plurality of electrical contacts on a first side of a substrate; wherein said electrical contacts include spiraling legs configured to create a wiping action on metal pads when compressed by said pads, and
a plurality of ball grid array balls on a second side of said substrate.

26. The interposer of claim 25, wherein said spiraling legs form a dome shape.

27. The interposer of claim 25, further comprising:
at least one micro stop of sufficient height to prevent over-compression of said spiraling legs of said electrical contacts on said first side of said substrate.

28. The interposer of claim 25, wherein said legs spiral in a clockwise direction.

29. The interposer of claim 25, wherein said legs spiral in a counter-clockwise direction.

30. The interposer of claim 25, wherein each of said electrical contacts comprise at least two legs.

31. The interposer of claim 25, wherein said electrical contacts are constructed from copper.

32. The interposer of claim 31, wherein said copper electrical contacts are plated with gold.

33. The interposer of claim 32, wherein said copper electrical contacts are further plated with nickel.

34. The interposer of claim 25, wherein said electrical contacts on said first side of said substrate are electrically connected by through-plated holes in said substrate to said ball grid array balls on said second side of said substrate.

35. The interposer of claim 10, wherein said legs of a plurality of said electrical contacts on said first side of said substrate spiral in a clockwise direction and said legs of a plurality of said electrical contacts on said first side of said substrate spiral in a counter-clockwise direction.

36. The interposer of claim 35, wherein substantially equal numbers of said legs of said electrical contacts on said first side of said substrate spiral in clockwise and counter-clockwise directions.
